(19) United States
(12) Patent Application Publication
(10) Pub. No.: US 2009/0166738 A1
(43) Pub. Date: Jul. 2, 2009

(54) RAM CELL INCLUDING A TRANSISTOR WITH FLOATING BODY FOR INFORMATION STORAGE HAVING ASYMMETRIC DRAIN/SOURCE EXTENSIONS

(76) Inventors: Nihar-Ranjan Mohapatra, Dresden (DE); Ralf Van Bentum, Moritzburg (DE)

Correspondence Address: WILLIAMS, MORGAN & AMERSON, 10333 RICHMOND, SUITE 1100, HOUSTON, TX, 77042, US

(21) Appl. No.: 12/144,202

(22) Filed: Jun. 23, 2008

(30) Foreign Application Priority Data
Dec. 31, 2007 (DE) 10 2007 063 231.4

(51) Int. Cl. H01L 27/12; H01L 21/84

(52) U.S. Cl. 257/347; 438/151; 257/E21.703; 257/E27.112

(57) ABSTRACT

In a floating body storage transistor, the dopant concentration at the emitter side of the parasitic bipolar transistor may be significantly increased on the basis of a tilted implantation process, while maintaining a desired graded dopant profile at the collector side. Consequently, voltages for reading and writing of the FB storage transistor may be reduced, thereby also reducing the amount of die area consumed by respective boost converters. In addition, reliability of the FB transistor, as well as the retention time, may be increased.

### BACKGROUND OF THE INVENTION

1. Field of the Invention

Generally, the present disclosure relates to the formation of integrated circuits, and, more particularly, to field effect transistors in complex circuits which may include a memory area formed according to an SOI architecture, wherein information is stored by controlling charge in a floating body of an SOI transistor.

2. Description of the Related Art

Integrated circuits typically comprise a great number of circuit elements on a given chip area according to a specified circuit layout, wherein advanced devices may comprise millions of signal nodes that may be formed by using field effect transistors. In the context of the present disclosure, the terms field effect transistors and MOS transistors are considered as synonyms. Thus, field effect transistors may represent a dominant component of modern semiconductor products, wherein advances in performance and low volume are mainly associated with a reduction of size of the basic transistor structures. Generally, a plurality of process technologies are currently practiced, wherein, for complex circuitry, such as microprocessors, storage chips, ASICs (application specific ICs) and the like, CMOS technology is currently one of the most promising approaches due to the superior characteristics in view of operating speed and/or power consumption and/or cost efficiency. During the fabrication of complex integrated circuits using CMOS technology, millions of complementary transistors, i.e., N-channel transistors and P-channel transistors, are formed on a substrate including a crystalline semiconductor layer. A MOS transistor, irrespective of whether an N-channel transistor or a P-channel transistor is considered, comprises so-called PN junctions that are formed by an interface of highly doped drain and source regions with an inversely or weakly doped channel region disposed between the drain region and the source region.

The conductivity of the channel region, i.e., the drive current capability of the conductive channel, is controlled by a gate electrode formed above the channel region and separated therefrom by a thin insulating layer. The conductivity of the channel region, upon formation of a conductive channel due to the application of an appropriate control voltage to the gate electrode, depends on the dopant concentration, the mobility of the majority charge carriers and, for a given extension of the channel region in the transistor width direction, on the distance between the source and drain regions, which is also referred to as channel length. Hence, in combination with the capability of rapidly creating a conductive channel below the insulating layer upon application of the control voltage to the gate electrode, the conductivity of the channel region substantially determines the performance of the MOS transistors. Thus, the latter aspect renders the reduction of the channel length a dominant design criterion for accomplishing an increase in the operating speed of the integrated circuits.

Due to the decreased dimensions of circuit elements, not only the performance of the individual transistor elements may be increased, but also their packing density may be improved, thereby providing the potential for incorporating increased functionality into a given chip area. For this reason, highly complex circuits have been developed, which may include different types of circuits, such as analog circuits, digital circuits and the like, thereby providing entire systems on a single chip (SoC). Furthermore, in sophisticated microcontroller devices, an increasing amount of storage capacity may be provided on a chip with the CPU core, thereby also significantly enhancing the overall performance of modern computer devices. For example, in typical microcontroller designs, different types of storage devices may be incorporated to provide an acceptable compromise between die area consumption and information storage density versus operating speed. For instance, fast or temporary memories, so-called cache memories, may be provided in the vicinity of the CPU core, wherein respective cache memories may be designed to allow for reduced access times compared to external storage devices. Since a reduced access time for a cache memory may typically be associated with a reduced storage density thereof, the cache memories may be arranged according to a specified memory hierarchy, wherein a level 1 cache memory may represent the memory formed in accordance with the fastest available memory technology. For example, static RAM memories may be formed on the basis of registers, thereby enabling an access time determined by the switching speed of the corresponding transistors in the registers. Typically, a plurality of transistors may be required to implement a corresponding static RAM cell. In currently practiced approaches, up to six transistors may typically be used for a single RAM memory cell, thereby significantly reducing the information storage density compared to, for instance, dynamic RAM memories including a storage capacitor in combination with a pass transistor. However, usage of storage capacitors may require a regular refreshing of the charge stored in the capacitor, while also writing to and reading from the dynamic RAM memory cell may require relatively long access times so as to appropriately charge and discharge the storage capacitor. Thus, although a high information storage density is provided, in particular, when vertical storage capacitor designs are considered, these memory devices may not be operated with high frequency and therefore dynamic RAM memories may typically be used for chip internal memories, for which an increased access time may be acceptable. For example, typical cache memories of level 3 may be implemented, in some cases, in the form of dynamic RAM memories to enhance information density within the CPU, while only moderately sacrificing overall performance.

Moreover, in view of further enhancing device performance, in particular, with respect to individual transistor elements, the SOI (semiconductor or silicon on insulator) architecture has continuously been gaining in importance for manufacturing fast transistors, due to their characteristics of a reduced parasitic capacitance of the PN junction, thereby allowing higher switching speeds compared to bulk transistors. In SOI transistors, the semiconductor region in which the drain and source regions, as well as the channel regions, are located, also referred to as body region, is dielectrically encapsulated. This configuration provides significant advantages, but also gives rise to a plurality of issues. Contrary to the body of bulk devices, which is electrically connected to the substrate, and thus applying a specified potential to the substrate maintains the body of the bulk transistor at a specified potential, the body of SOI transistors is not connected to a specified reference potential. Hence, the body's potential may usually float, due to accumulating charge carriers which may be generated by impacted ionization and the like, thereby leading to a variation of the threshold voltage (Vt) of the transistors, depending on the “switching history” of the transistor, which may also be referred to as hysteresis. The threshold voltage represents the voltage at which a conductive channel forms in the body region between the drain region and the source region of the transistor.

The floating body effect is considered disadvantageous for the operation of regular transistor elements, for instance, in particular, for static RAM memory cells, since the operation-dependent threshold voltage variation may result in significant instabilities of the memory cell, which may not be tolerable in view of data integrity of the memory cell. Consequently, in conventional SOI devices including memory blocks, the drive current fluctuations associated with the threshold voltage variations are taken into consideration by appropriate design measures in order to provide a sufficiently high drive current range of the SOI transistors in the memory block. However, with respect to increasing information density for memory devices compared to static RAM memories and also compared to dynamic RAM memories, as previously explained, the floating body effect and the variation of the threshold voltage associated therewith may be taken advantage of by using the floating body of an SOI transistor as a charge storage region. In this manner, information may be stored in the transistor itself, thereby no longer requiring a charge storage capacitor, as in dynamic RAM cells, while also providing the potential for achieving five times the density of current static RAM memories typically comprising six transistor elements.

Consequently, so-called floating body storage transistors have been developed, in which charge may intentionally be accumulated in the body region so as to represent a logic high or low state, depending on the memory technique.

FIG. 1a schematically illustrates a cross-sectional view of a conventional floating body storage transistor 100 in the form of an N-channel transistor comprising a substrate 101, including a buried insulating 102, above which is formed a silicon layer 103. Thus, the substrate 101, the buried insulating layer 102, for instance, provided in the form of silicon dioxide, and the silicon layer 103 define an SOI configuration. The transistor 100 further comprises a gate electrode structure 104 including a gate electrode 104B formed on a gate insulation layer 104A. Moreover, a sidewall spacer structure 106 is formed on the sidewalls of the gate electrode structure 104. Furthermore, the storage transistor 100 comprises drain and source regions 105, each of which comprises a lightly doped region 105B adjacent to the gate electrode structure 104 and a highly doped region 105A that is offset from the gate electrode structure 104, for instance, by a distance substantially defined by the sidewall spacer structure 106. The lightly doped regions 105B form respective PN junctions 105C with a body region 107, which represents a floating body region since electrical connection to the periphery may be established via the respective PN junctions 105C only. Furthermore, the transistor 100 may comprise respective contact areas 108, for instance, comprised of an appropriate metal silicide and the like. Additionally, the transistor 100 may be connected to voltage nodes indicated as V_{BC}, V_{WC} and V_{SC}, which may represent a bit line, a word line and a select line or respective voltages conveyed by these lines as may typically be provided in memory areas.

The transistor 100 may be formed on the basis of well-established process techniques for forming SOI transistors, including processes for forming and patterning the gate electrode structure 104, forming the lightly doped region 105B on the basis of ion implantation, followed by the formation of the spacer structure 106, which may be used as an efficient implantation mask during the formation of the highly doped regions 105A. Appropriate anneal cycles may be performed to activate the dopants and re-crystallize any damage in the silicon layer 103. Thereafter, the contact areas 108 may be formed and an appropriate contact structure and metallization system may be established to obtain the bit line, the word line and the select line or source line.

During operation of the storage transistor 100, a moderately high voltage may be applied to the select line to create respective electron/hole pairs by impact ionization or band gap bending mechanisms, wherein holes as majority charge carriers for the body region 107 may accumulate in the body region, while the electrons may drain off via the select line due to the applied high voltage. Operating the transistor 100 in this high voltage mode may be understood by referring to the lateral parasitic bipolar transistor 109, which may represent an NPN transistor defined by the lightly doped regions 105B and the floating body region 107. Thus, by taking advantage of the parasitic transistor 109, charge may be created and accumulated in the body region 107, which may then significantly affect the threshold voltage of the transistor 100, which, although being considered as disadvantageous in standard SOI transistors, may be used for storing information in the transistor 100. Thus, the overall operational behavior of the storage transistor 100 may strongly depend on the characteristics of the parasitic transistor 109 and thus on the configuration of the body region 107 and the lightly doped regions 105C. Consequently, the voltage provided at the select line may have to be adapted to the characteristics of the parasitic transistor 109 and thus to the overall configuration of the transistor 100.

FIG. 1b schematically illustrates a top view of a semiconductor device comprising an array 110 of storage transistors 100 with respective word lines, which may represent the gate electrode structures 104, a bit line 111 and a select line 112. Furthermore, as schematically illustrated, a control logic 120 may be connected to the array 110. Additionally, a voltage step-up converter 130 may be provided to create the required high voltages for operating the array 110. For example, the voltage step-up converter 130 may be provided in the form of a charge pump, wherein typically the area required for forming the circuit on the substrate 101 of the device may typically increase as the degree of boosting the voltage increases. Consequently, the area consumed by the peripheral circuits may increase if the voltage for operating the floating body RAM array 110 may increase. In addition, by applying a moderately high voltage to the transistor 100, respective leakage currents may also increase, thereby negatively impacting the retention time of the transistor 100.

Consequently, although transistors using the floating body as an efficient information storage component provide a significant area saving compared to static RAM devices and dynamic RAM devices using a storage capacitor, there is still room for improvement with respect to reducing area consumption caused by auxiliary circuits and leakage currents of the storage transistors.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the subject matter disclosed herein relates to semiconductor devices and techniques in which the operating voltage of floating body storage transistors may be reduced by enhancing the characteristics of a parasitic bipolar transistor. For this purpose, the “current” amplification coefficient (beta) of the parasitic transistor may be increased by appropriately modifying the dopant concentration, while nevertheless providing a desired graded dopant profile in the vicinity of the gate edge experiencing a high electric field during operation of the floating body transistor. Consequently, by appropriately increasing the dopant concentration at the emitter side of the parasitic transistor while maintaining a graded dopant profile at the collector side thereof, the magnitude of the operating voltage for read and write operations of the transistor may be reduced, thereby enhancing the reliability of the floating body memory cell, while also improving data retention time due to the reduction of the leakage current. In addition, since the operating voltage may be reduced, an area consumed by the periphery circuitry, such as voltage step-up converters and the like, may also be reduced, thereby enhancing the overall information storage density of respective memory areas.

One illustrative semiconductor device disclosed herein comprises a memory area comprising a substrate, a buried insulating layer and a semiconductor layer which commonly define an SOI configuration. The semiconductor device further comprises a storage transistor configured to store charges in a floating body region thereof, wherein the storage transistor comprises an asymmetric configuration with respect to a lateral dopant distribution in a drain region and a source region.

A further illustrative semiconductor device disclosed herein comprises a memory area comprising a substrate, a buried insulating layer and a semiconductor layer to define an SOI configuration. The semiconductor device further comprises a plurality of storage transistors configured to store information on the basis of charge storage in a floating body region of the storage transistors, wherein each of the plurality of storage transistors has an asymmetric configuration with respect to a lateral dopant distribution in drain and source regions of the storage transistors. Furthermore, a peripheral device area is provided and comprises a voltage boost converter configured to provide an up-converted voltage to the memory area.

One illustrative method disclosed herein relates to the formation of a storage transistor and comprises forming a gate electrode structure above a semiconductor layer that is formed on a buried insulating layer. The method further comprises asymmetrically introducing a dopant species into the semiconductor layer adjacent to the gate electrode structure to form a lightly doped region and a highly doped region, wherein the lightly doped region and the highly doped region form respective PN junctions with a body region located adjacent to the gate electrode structure.

### BRIEF DESCRIPTION OF THE DRAWINGS

The disclosure may be understood by reference to the following description taken in conjunction with the accompanying drawings, in which like reference numerals identify like elements, and in which:

FIG. 1a schematically illustrates a cross-sectional view of a floating body storage transistor of one transistor memory cell without a storage capacitor, according to conventional techniques;

FIG. 1b schematically depicts an array of conventional floating body transistors with a voltage step-up converter, according to the conventional approach;

FIGS. 2a-2b schematically illustrate cross-sectional views of a semiconductor device during various manufacturing stages in forming an asymmetric configuration for a floating body storage transistor, according to illustrative embodiments;

FIG. 2c schematically illustrates the semiconductor device according to further illustrative embodiments, in which an asymmetric configuration may be obtained prior to forming a sidewall spacer structure;

FIG. 2d schematically illustrates a top view of a memory area of a semiconductor device including a plurality of floating body storage transistors, according to illustrative embodiments;

FIGS. 2e-2f schematically illustrate complex semiconductor devices including a floating body RAM memory area on the basis of asymmetrically designed storage transistors, according to illustrative embodiments; and

FIG. 2g schematically illustrates a cross-sectional view of a semiconductor device comprising a floating body or RAM area and a static RAM area formed on the basis of a bulk configuration, according to still further illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present disclosure contemplates semiconductor devices and techniques for forming the same, wherein floating body storage transistors (FB transistors) may be provided with an asymmetric configuration with respect to a lateral dopant profile in order to enhance the performance of the parasitic bipolar transistor by increasing the drive current capability for a given operational voltage. That is, the “beta,” the “current amplification factor,” may be increased by increasing the dopant concentration at the emitter side of the parasitic transistor, while nevertheless providing a graded dopant profile at the collector side. Consequently, a desired generation of electron/hole pairs in the floating body and a respective accumulation of the majority charge carriers of the floating body may be accomplished at reduced read and write voltages compared to conventional FB transistors having a symmetric design with respect to their drain and source regions. In some illustrative embodiments, the asymmetric design may be accomplished on the basis of an ion implantation sequence including at least one implantation step performed on the basis of an appropriately selected tilt angle so as to introduce the dopant species preferably at the emitter side of the parasitic transistor while a gate electrode structure may substantially block or at least significantly suppress the penetration of dopant species at the collector side of the parasitic bipolar transistor. In this case, a highly efficient manufacturing flow may be obtained, since any process steps for forming an implantation mask may be avoided. In other cases, appropriate implantation masks may be formed, thereby providing enhanced flexibility in aligning the respective FB transistors in a memory area.

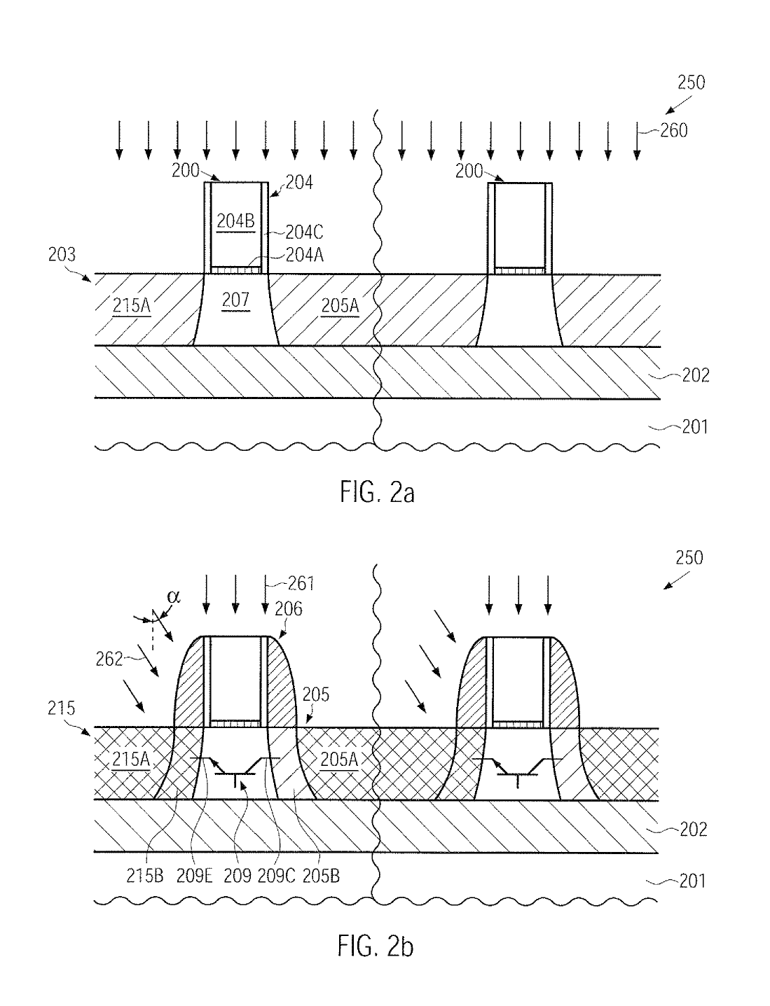

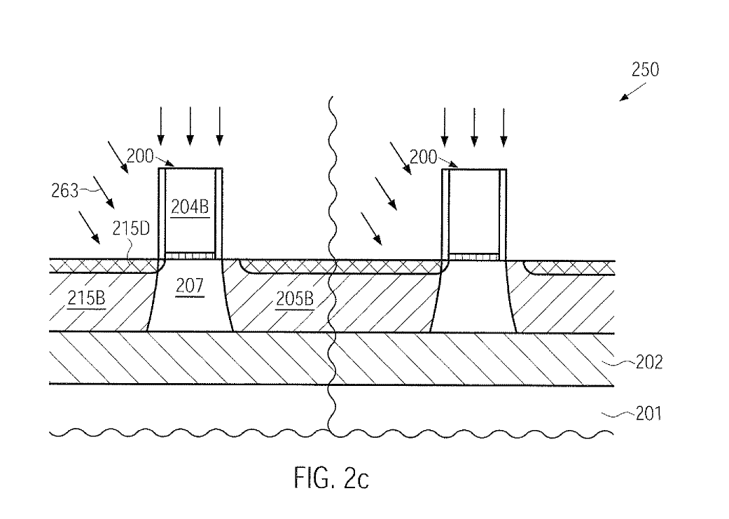

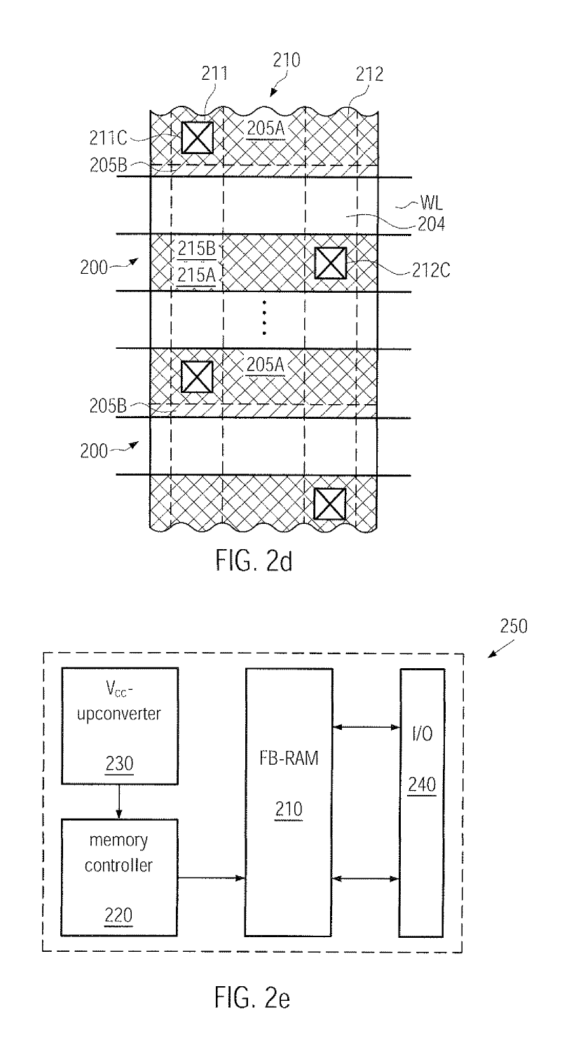

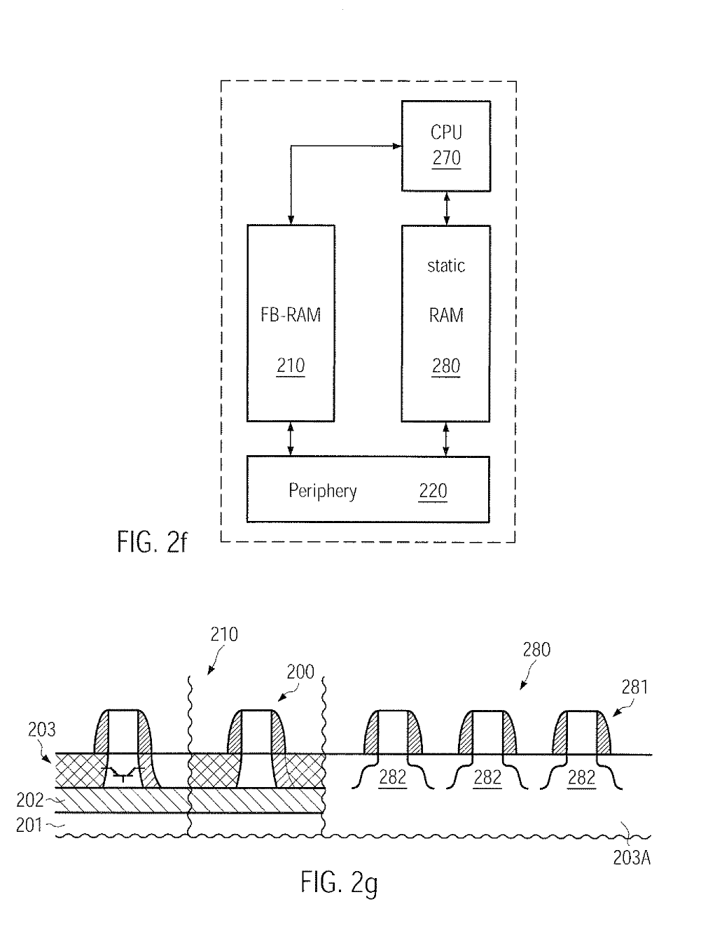

FIG. 2a schematically illustrates a cross-sectional view of a semiconductor device 250, which may comprise a substrate 201, a buried insulating layer 202 and a semiconductor layer 203 formed on the buried insulating layer 202. It should be appreciated that the semiconductor device 250 may comprise other device regions (not shown), in which the SOI configuration defined by the substrate 201, the buried insulating layer 202 and the semiconductor layer 203 may not be defined. For example, as will be described later on in more detail, certain device areas of the device 250 may be provided in the form of a bulk configuration, in which the semiconductor layer 203 may be formed on a crystalline semi-conductor material. It should further be appreciated that the semiconductor layer 203 may represent any appropriate semiconductor material, comprising, for instance, silicon, germanium, carbon and the like, as may be required for adjusting the overall characteristics of respective storage transistors 200 that are formed in and above the semiconductor layer 203. Similarly, the buried insulating layer 202 may be made of any appropriate material, such as silicon dioxide, silicon nitride and the like. In the manufacturing stage shown, the storage transistors 200 may comprise a gate electrode structure 204 including a gate electrode material 204B, such as polysilicon and the like. Furthermore, a gate insulation layer 204A having any required thickness and material composition may be provided to separate the gate electrode material 204B from a body region 207. Furthermore, in some illustrative embodiments, the gate electrode structure 204 may comprise an offset spacer 204C, which may be provided in the form of silicon dioxide, silicon nitride, silicon oxynitride or any other appropriate dielectric material. The offset spacer 204C may have a width that may provide a desired offset with respect to the gate insulation layer 204A during an ion implantation process 260. Respective lightly doped regions 205A, 215A may be formed within the semiconductor layer 203, with an offset with respect to the gate insulation layer 204A that is substantially determined by the width of the offset spacer 204C.

The semiconductor device 250 as shown in FIG. 2a may be formed on the basis of similar process techniques as are previously described with reference to the storage transistor 100. That is, the SOI configuration in the device region of the device 250 as shown in FIG. 2a may be established on the basis of any appropriate technique, which may include wafer bond techniques, the creation of the buried insulating layer 202 on the basis of implantation of oxygen with a subsequent heat treatment and the like. Thereafter, well-established techniques may be used for forming the gate electrode structure 204, wherein respective dimensions, such as the gate length, i.e., the horizontal dimension of the gate electrode 204B, may be adjusted in accordance with the design rules for the device 250. Prior to forming the gate electrode structure 204, any appropriate implantation processes may have been performed to adjust the overall characteristics of the semiconductor layer 203 for forming the transistors 200. For example, the basic dopant implantation for defining the conductivity type, the adjustment of the threshold voltages and the like may be accomplished on the basis of ion implantation techniques. After forming the gate electrode structure 204, the offset spacer 204C, if required, may be formed by deposition and etch techniques, using well-established process recipes. Thereafter, the implantation process 260 may be performed by introducing a dopant species, such as an N-type species for forming the transistors 200 in the form of N-channel transistors, while introducing a P-type dopant species when forming the transistors 200 as P-channel transistors. It should be appreciated that the respective implantation species used for establishing the basic dopant concentration, as well as the adjustment of threshold voltage and the like, may also have to be adapted to the conductivity type of the transistors 200. The dopant concentration in the lightly doped regions 205A, 215A may be selected such that an electric field generated by applying a high required operating voltage to the region 205A may be compatible with the device requirements, similarly as in conventional symmetric drain and source designs.

FIG. 2b schematically illustrates the semiconductor device 250 in a further advanced manufacturing stage. As shown, the transistors 200 may comprise a sidewall spacer structure 206 having a desired spacer to provide a graded dopant concentration at one side of the gate electrode structure 204. As shown, the sidewall spacer structure 206 may protect the lightly doped regions 205B, 215B during an ion implantation process 261. Moreover, in a further implantation process 262, additional dopant species may be introduced in an asymmetric manner to increase the dopant concentration in the region 215B while substantially avoiding additional incorporation of dopant species into the lightly doped region 205B. For this purpose, the implantation process 262 may be performed on the basis of an appropriately selected tilt angle, which is to be understood as an angle α defined by a substantially orthogonal direction with respect to the semiconductor layer 203 and the direction of the ion beam moving towards the device 250. For example, the tilt angle α may vary in the range of approximately 20-45 degrees, wherein also other implantation parameters, such as dose and energy, may be appropriately selected so as to enrich the region 215B with additional dopant species. For example, for moderately low tilt angles in the range of 20 degrees, respective higher energies may be used which may be comparable to the energy values used during the implantation process 261. It should be appreciated that appropriate precise parameters may be selected on the basis of simulation and/or experiments in order to obtain a desired high dopant concentration in the region 215B, while not unduly influencing the overall channel length in the body region 207.

During the implantation process 262, the gate electrode structure 204 may act as an efficient implantation mask for shielding at least the portion 205B and also a portion of the region 205A, thereby substantially maintaining the desired graded dopant profile. After the implantation processes 261, 262, an appropriately designed anneal process may be performed to activate the dopant species and re-crystallize implantation-induced damage. During a respective anneal process, depending on the process parameters, a certain degree of dopant diffusion may be initiated, if required, thereby more uniformly distributing the dopant species additionally introduced during the implantation process 262. In other cases, a significant dopant diffusion may be suppressed by appropriately selecting the anneal process parameters.

Consequently, a parasitic bipolar transistor 209, in the embodiment shown an NPN transistor corresponding to the N-channel configuration and the transistors 200, may be defined by the body region 207 and the regions 215B to 205B. As shown, the region 205B may correspond to a collector 209C, while the region 215B having the additionally incorporated dopant species may represent an emitter 209E. It should be appreciated that the regions 205B, 205A may be referred to as a drain or source region 205, depending on the circumstances during operation of the transistors 200. Similarly, the regions 215B, 215A may commonly be referred to as drain/source region 215 so that the transistors 200 may comprise an asymmetric configuration with respect to their drain and source regions in view of the lateral dopant concentration.

FIG. 2c schematically illustrates the semiconductor device 250 according to further illustrative embodiments, in which, additionally or alternatively, a tilted implantation process 263 may be performed prior to or after the implantation process 260 for defining the lightly doped regions 205B, 215B. In one illustrative embodiment, the implantation process 263 may be performed on the basis of a reduced implantation energy so as to avoid significant penetration into the body region 207 below the gate electrode structure 204. In this case, a moderately shallow region 215D of increased dopant concentration may be formed in the region 215B such that, in combination with the implantation process 262 (FIG. 2b), a moderately high dopant concentration may also be obtained in an upper portion of the region 215B, which may be moderately shaded during the implantation 262. On the other hand, the respective region 215D in lightly doped region 215B may be offset from the gate electrode structure 204 due to the blocking effect thereof. For example, a tilt angle during the implantation process 263 may be selected such that a similar offset may be obtained at the side of the region 205B as may be provided by the spacer structure 206 during the implantation process 261 as shown in FIG. 2b. Thus, also during the implantation process 263, a negative impact of the additionally provided dopant species may be substantially avoided at the collector side 209C of the parasitic transistor 209.

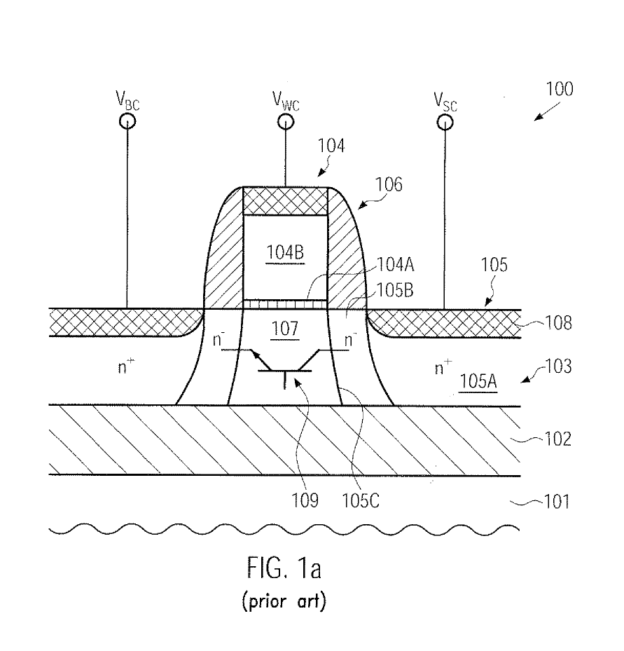

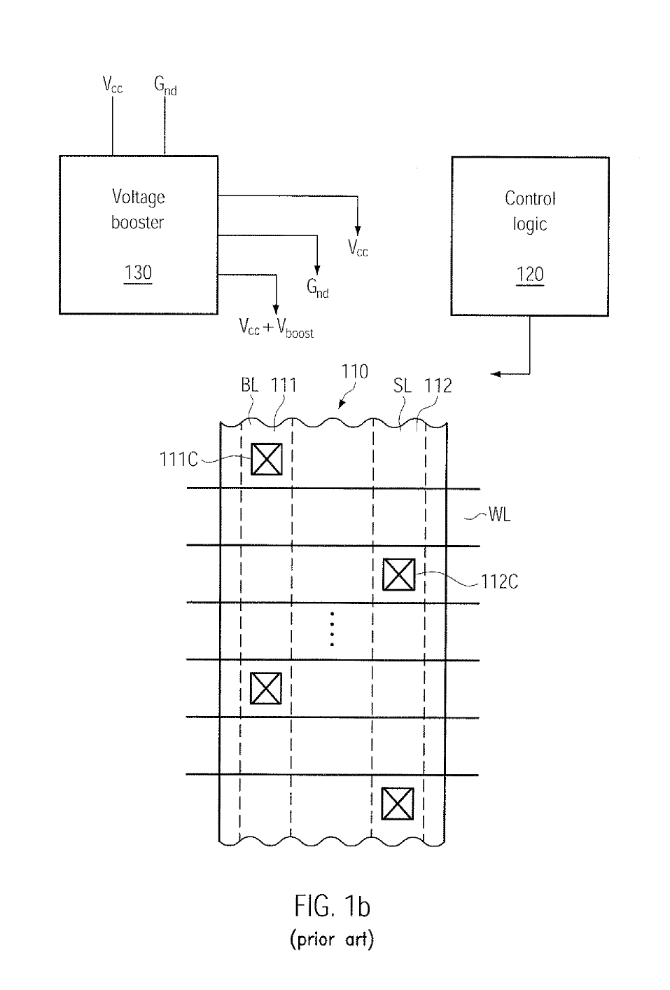

Thereafter, the further processing may be continued by forming contact areas, such as metal silicide regions, if required, as is also described with reference to the transistor 100 in FIG. 1a. Thereafter, an appropriate contact structure may be formed and a metallization system may be provided to appropriately connect the transistors 200 in order to form a memory array of a desired size.

FIG. 2d schematically illustrates a top view of the device 250 according to illustrative embodiments, in which a plurality of FB transistors 200, for instance, in the form of N-channel transistors as shown in FIG. 2b or in the form of P-channel transistors (not shown), may be combined so as to form an array 210 of memory cells comprised of individual transistors 200 without storage capacitors. For convenience, the sidewall spacer structure 206, as well as an interlayer dielectric material, is not shown in FIG. 2d. Furthermore, respective metal lines 211, 212 acting as the bit line and the select line, which may typically be formed in a metallization layer of the device 250, may be illustrated in dashed lines. Respective contacts 210C, 212C may provide an electrical connection between the region 205 and 215 with the lines 211 and 212. Furthermore, as illustrated, respective word lines may be represented by the electrode structures 204. It should be appreciated that the array 210 as illustrated in FIG. 2d may represent a one-dimensional array for convenience, wherein typically a plurality of transistor elements may be provided along a transistor width direction, which represents the horizontal direction in FIG. 2d, so as to define a two-dimensional memory array. Furthermore, the transistors 200 may be oriented in a parallel manner with respect to the transistor width direction such that the highly doped regions 215B, 215A of one transistor may face that side of an adjacent transistor 200 that comprises therein a graded dopant profile in the form of the lightly doped region 205B and the highly doped region 205A. Consequently, according to this configuration, each of the transistors 200 may receive the asymmetric configuration on the basis of a common implantation sequence comprising the tilted implantation processes 262 and/or 263, as previously explained. Hence, additional process steps for forming implantation masks may be avoided. In other illustrative embodiments, appropriate masking regimes in the form of resist masks and the like may be used, when some of the transistors 200 may require a tilted implantation from one side, while other transistors 200 may require a tilted implantation from the opposite side.

As a consequence, the transistors 200 as described above may have an asymmetric configuration with respect to the drain and source areas, wherein the dopant concentrations in the regions 215B may be adjusted so as to be approximately five times the dopant concentration in the lightly doped region 205B. In still further illustrative embodiments, the dopant concentration in the regions 215B may be approximately 10-100 times the concentration in the lightly doped region 205B. It should be appreciated that the dopant concentration may vary in the regions 215B and 205B and the above-defined values representing the difference may refer to any appropriate representative concentration value for the regions 215B, 205B. For instance, a maximum dopant concentration at the respective PN junctions defined by the regions 215B and 205B with the body region 207 may be used to quantitatively compare the respective concentration values. Thus, the emitter doping of the parasitic transistor 209 may be significantly increased, while substantially not affecting the collector doping, so that an electrical field strength at the respective edge of the gate electrode structures 204 at the collector side may be maintained at an appropriate low value. Hence, the overall reliability of the transistors may be enhanced due to the reduced maximum operating voltages, while the magnitude of the leakage currents may also be reduced, thereby increasing the data retention time of the transistors due to the reduced degree of losing charge stored in the body region 207.

With reference to FIGS. 2e-2g, further illustrative embodiments will now be described, wherein a memory area including the array 210 may be incorporated into various device architectures.

FIG. 2e schematically illustrates the semiconductor device 250 according to further illustrative embodiments, in which an asymmetrical floating body RAM area, for instance in the form of the array 210, may be provided in an appropriate circuit portion of the device 250, or the device 250 may represent a memory device usable as storage device for other components external to the device 250. For this purpose, the device 250 may further comprise a voltage step-up converter 230, which may be configured to boost the supply voltage of the device 250 to an appropriate high value required for operating the array 210 as previously explained with reference to FIG. 1b. Furthermore, a memory controller 220 may be provided to control read and write operations in the array 210 by appropriately switching voltage signals on the respective lines, such as the word line and the bit line and select line 211, 212 as previously discussed. Furthermore, in one illustrative embodiment, the device 250 may further comprise an input/output circuitry 240 to allow access to the asymmetric RAM memory 210 by external devices.

During operation of the device 250, respective high voltages may be supplied during reading and writing to individual cells of the FB-RAM 210, wherein, due to the increased emitter doping of the parasitic transistor 209, i.e., the regions 215B, a reduced operating voltage may be supplied to the region 205 compared to conventional symmetric designs. For instance, compared to an otherwise identical FB-RAM formed according to a conventional symmetric device configuration, a reduction of approximately 10-15% in the read and write voltages may be achieved, thereby reducing the overall leakage currents in the array 210, as previously explained. Furthermore, the chip area consumed by the step-up converter 230 may be reduced, thereby providing an increased information storage density of the device 250, since for a given number of FB memory cells the size of the auxiliary circuits, i.e., the step-up converter 230, and thus the size of the overall device 250 may be reduced.

FIG. 2f schematically illustrates the semiconductor device 250 according to a further illustrative embodiment. As shown, the device 250 may represent an advanced integrated circuit including central processing unit (CPU) 270, which may be operatively connected to a static RAM area, which may, for instance, comprise memory cells having a low access time, for instance, based on conventional registers. For example, the static RAM area 280 may represent a cache memory for the CPU 270, for example, including a level 1 cache memory and a level 2 cache memory. Moreover, the device 250 may comprise an asymmetric FB-RAM area 210, for instance in the form of an array as previously described, which may comprise respective asymmetric transistors as previously explained with reference to the transistors 200. Moreover, a peripheral circuitry 220 may be provided that may control the memory areas 210, 280, for instance, by providing appropriate control signals and supply voltages as required for the operation of the areas 280, 210. In one illustrative embodiment, the asymmetric FB-RAM area 210 may represent a level 3 cache memory for the CPU 270. In this case, an enhanced storage density may be obtained, since the memory area 210 may have a significantly increased storage density compared to static RAM arrays, as previously explained, and may also provide a significantly increased storage density compared to dynamic RAM devices, since no storage capacitor is required. Furthermore, due to the enhanced reliability and increased retention time, enhanced overall performance of the device 250 may be accomplished compared to conventional devices including a highly complex CPU, since an increased amount of storage capacity may be provided or additional functionality may be incorporated into the device 250 due to the space saving accomplished by providing the asymmetric FB-RAM 210.

As previously explained, static RAM cells may suffer from increased threshold variability when formed on the basis of an SOI configuration. In this case, a drive current capability of the respective SOI transistors may have to be increased so as to take into consideration the increased threshold variability. Thus, in one illustrative embodiment disclosed herein, a further overall reduction in size may be accomplished by providing a static RAM area in combination with an asymmetric FB-RAM area, wherein, however, the static RAM area may be formed on the basis of bulk transistors.

FIG. 2g schematically illustrates a cross-sectional view of the semiconductor device 250, which may comprise an asymmetric memory area, for instance, the area 210 including the transistors 200, as previously explained, while the static RAM area, such as the area 280, may comprise N-channel transistors and P-channel transistors 281 formed on the basis of a semiconductor layer 203A having an appropriate thickness such that respective body regions 282 of transistors of the same conductivity type may be electrically connected to each other via the layer 203A, thereby defining a “bulk” configuration for the transistors 281. Hence, by applying a specified potential to the semiconductor layer 203A, i.e., to the respective portions connecting the body regions 282 of transistors of the same conductivity type, the threshold variability may be significantly reduced thereby allowing forming of the transistors 281 on the basis of a reduced current drive capability and thus reduced transistor dimensions. Consequently, in combination with the asymmetric memory area 210, a further enhanced overall storage capacity may be obtained for a given chip area.

As a result, the present disclosure provides semiconductor devices and manufacturing techniques for obtaining an asymmetric configuration of FB storage transistors, which enable operation of a floating body memory area on the basis of reduced voltages during writing and reading of respective memory cells. Consequently, the overall reliability may be increased by reducing leakage currents and also reducing respective electrical field strengths, while at the same time providing reduced area consumption, since respective boost converters providing the required voltages may be reduced in size. For this purpose, the emitter doping of the parasitic bipolar transistor in the FB storage transistor may be significantly increased, while, on the other hand, maintaining a desired graded dopant profile at the collector side of the bipolar transistor.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A semiconductor device, comprising:
a memory area comprising a substrate, a buried insulating layer and a semiconductor layer so as to define an SOI configuration; and
a storage transistor configured to controllably store charges in a floating body region thereof, said storage transistor comprising an asymmetric configuration with respect to a lateral dopant distribution in a drain region and a source region.

2. The semiconductor device of claim 1, wherein a dopant gradient of a PN junction formed at an emitter side of a parasitic bipolar transistor of said storage transistor is steeper compared to a dopant gradient of a PN junction formed at a collector side of said parasitic bipolar transistor.

3. The semiconductor device of claim 2, wherein a maximum dopant concentration of the PN junction at said emitter side is at least approximately five times the maximum dopant concentration of said PN junction at said collector side.

4. The semiconductor device of claim 3, wherein said maximum dopant concentration of the PN junction at said emitter side is approximately 10-100 times the maximum dopant concentration of said PN junction at said collector side.

5. The semiconductor device of claim 1, further comprising a plurality of storage transistors, including said storage transistor, said plurality of storage transistors defining an array of memory cells.

6. The semiconductor device of claim 5, wherein transistor width directions of said plurality of storage transistors are oriented in parallel and a collector side of a respective parasitic bipolar transistor of a first one of two adjacent storage transistors faces an emitter side of the parasitic bipolar transistor of a second one of said two adjacent storage transistors.

7. The semiconductor device of claim 5, further comprising a bit line connecting the drain regions of said plurality of storage transistors, a source line connecting the source regions of said plurality of storage transistors.

8. The semiconductor device of claim 7, wherein said plurality of storage transistors represent N-channel transistors.

9. A semiconductor device, comprising:
a memory area comprising a substrate, a buried insulating layer and a semiconductor layer so as to define an SOI configuration;
a plurality of storage transistors configured to store information on the basis of charge storage in a floating body region of the storage transistors, each of said plurality of storage transistors having an asymmetric configuration with respect to a lateral dopant distribution in drain and source regions of said storage transistors; and
a peripheral device area comprising a voltage boost converter configured to provide an up-converted voltage to said memory area.

10. The semiconductor device of claim 9, further comprising a CPU core operatively connected to said memory area.

11. The semiconductor device of claim 10, further comprising a static RAM area operatively connected to said CPU core and said memory area.

12. The semiconductor device of claim 11, wherein said static RAM area is formed of transistors having a bulk architecture.

13. The semiconductor device of claim 9, wherein a dopant gradient of a PN junction formed at an emitter side of a parasitic bipolar transistor of each of said plurality of storage transistors is steeper compared to a dopant gradient of a PN junction formed at a collector side of said parasitic bipolar transistor.

14. The semiconductor device of claim 9, wherein said maximum dopant concentration of the PN junction at said emitter side is approximately 5-100 times the maximum dopant concentration of said PN junction at said collector side.

15. A method of forming a storage transistor, the method comprising:
forming a gate electrode structure above a semiconductor layer formed on a buried insulating layer; and
asymmetrically introducing a dopant species into said semiconductor layer adjacent to said gate electrode structure to form a lightly doped region and a highly doped region, said lightly doped region and said highly doped region forming respective PN junctions with a body region located adjacent to said gate electrode structure.

16. The method of claim 15, wherein asymmetrically introducing said dopant species comprises performing an ion implantation process including an implantation step using a tilt angle.

17. The method of claim 16, wherein asymmetrically introducing said dopant species comprises forming lightly doped regions adjacent to said gate electrode structure, forming highly doped regions with a specified offset to said gate electrode structure and performing a first implantation step using a first tilt angle so as to increase a dopant concentration in one of said lightly doped regions.

18. The method of claim 17, further comprising forming a spacer on sidewalls of said gate electrode structure prior to forming said highly doped regions and performing said first implantation step after forming said spacer.

19. The method of claim 17, further comprising forming a spacer on sidewalls of said gate electrode structure prior to forming said highly doped regions and performing said first implantation step prior to forming said spacer.

20. The method of claim 18, further comprising performing a second implantation step using a second tilt angle prior to forming said spacer.

21. The method of claim 19, further comprising performing a second implantation step using a second tilt angle after forming said spacer.
